(19) United States
(12) Patent Application Publication
(10) Pub. No.: US 2006/0274515 A1
(43) Pub. Date: Dec. 7, 2006

(54) Methods and apparatus for a configurable chassis

(75) Inventors: James G. Arthur, Morgan Hill, CA (US); Lyle S. Looney, Livermore, CA (US); Alvan R. Tom, Los Altos, CA (US)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: Tellabs San Jose, Inc., San Jose, CA (US)

(21) Appl. No.: 11/264,895

(22) Filed: Nov. 1, 2005

Related U.S. Application Data
(60) Provisional application No. 60/686,996, filed on Jun. 4, 2005.

(51) Int. Cl. H05K 7/14

(52) U.S. Cl. 361/796

(57) ABSTRACT

A system of circuit board chassis can be configured to accept different types of circuit boards or modules. In one embodiment, a first chassis is adapted to receive a first type of circuit board, and a second chassis is adapted to fit inside the first chassis in place of at least one of the circuit boards. In this embodiment, the second chassis is also adapted to receive circuit boards of a second type, enabling them to operate inside the first chassis. As a result, a system that may have been previously adapted to receive only one type of circuit board may be configured to operate with multiple types of circuit boards.

### RELATED APPLICATION

This application claims the benefit of U.S. Provisional Application No. 60/686,996, filed on Jun. 4, 2005. The entire teachings of the above application are incorporated herein by reference.

### BACKGROUND OF THE INVENTION

Communications systems are typically modular in design, made of various communications modules that include hardware and software that transmit inter-module communications signals (e.g., voice, data, or packets) running through the communications system. A subsystem of a communications system may comprise a number of communications modules that connect to a common circuit, such as a backplane or midplane, through which signals are transmitted between communications modules and throughout the system.

Typical subsystems include an interface and support structure by which the communications modules connect to the subsystem. For communications modules comprising circuit boards, this structure is typically a chassis that supports a backplane, and circuit board guides that help the communications modules connect with socket(s) on the backplane and secure the connected modules in place.

### SUMMARY OF THE INVENTION

Embodiments of the present invention may be used to position multiple types of modules, such as communications modules, in a single subsystem. In one embodiment, a first chassis is adapted to receive a first type of circuit board, and a second chassis is adapted to fit inside the first chassis in place of at least one circuit board. In this embodiment, the second chassis is also adapted to receive circuit boards of a second type, enabling them to operate inside the first chassis. As a result, embodiments of the present invention allow a system, which may have been previously adapted to receive only one type of circuit board, to operate with multiple types of circuit boards.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is an illustration of a modular communications system.

FIG. 2 is an illustration of a second communications system.

FIG. 3A is an illustration of a system having a first chassis of an exemplary embodiment of the present invention.

FIG. 3B is an illustration of a module subsystem adapted for operation in the system of FIG. 3A.

FIG. 3C is an illustration of the system of FIG. 3A with the module subsystem of FIG. 3B inserted into the topmost slot.

FIG. 3D is an illustration of a second chassis adapted for use in the first chassis of FIG. 3A, as an exemplary embodiment of the present invention.

FIG. 3E is an illustration of a configuration of the system of FIG. 3A, with a module subsystem, and a second chassis, with cards, inserted into the first chassis.

FIG. 3F is an illustration of a second configuration of the system of FIG. 3A, with multiple second chassis with cards inserted into all slots of the first chassis.

FIG. 3G is an illustration of the system of FIG. 3A with a module subsystem of FIG. 3B being inserted into the top position and multiple second chassis being inserted into the first chassis.

FIG. 4A is an example method of manufacturing a system having a first chassis and at least one second chassis.

FIG. 4B is an example method of manufacturing a panel with a ventilation hole for use with the second chassis.

### DETAILED DESCRIPTION OF THE INVENTION

A description of preferred embodiments of the invention follows.

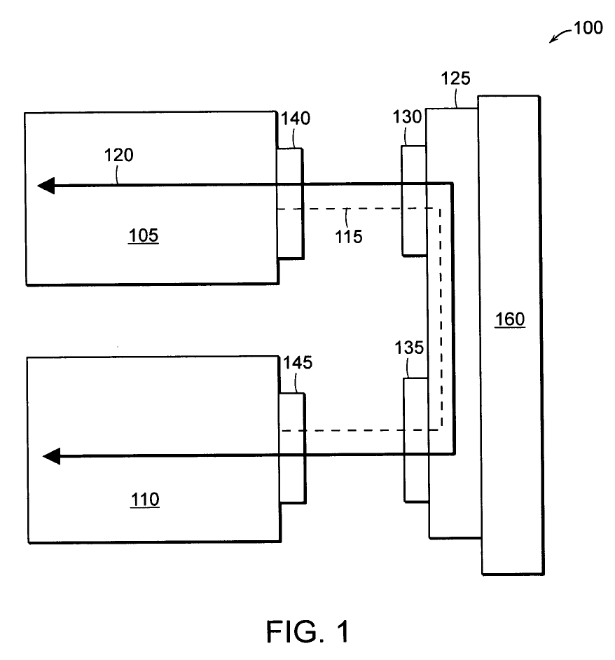

FIG. 1 illustrates a subsystem 100 in which an embodiment of the present invention may be employed. The subsystem 100 may be an exemplary communications system, having communications modules 105, 110 (hereinafter interchangeably referred to as a “card”), a backplane 125, and a multiple card-holding structure 160 (hereinafter referred to as “chassis”). Inter-module communications signals 115 run between communications modules 105, 100 and through the backplane 125, and communications traffic 120 is transmitted through the subsystem 100. Each card 105, 110 may be a circuit board, multiple circuit boards, or other substrate that holds electrical, optical or other components. Also mounted on each card are traces between the components, allowing the components to communicate among each other.

At the edge of each card 105, 110 is a card edge connector 140, 145, which can mate with respective backplane sockets 130, 135. Typically, traces are located within the backplane sockets 130, 135 and the card edge connectors 140, 145, so that upon the mating of a connector to a socket, the traces permit communication or transmission of communication, data clock, or other signals between a card 105, 110 and the backplane 125. Because other communications modules (not shown) can be similarly connected to the backplane 125, providing the modules are adapted to connect to and operate with the backplane 125, the backplane 125 provides a channel for communications between multiple cards, as illustrated, for example, by a dashed line representing inter-module communications signals 115.

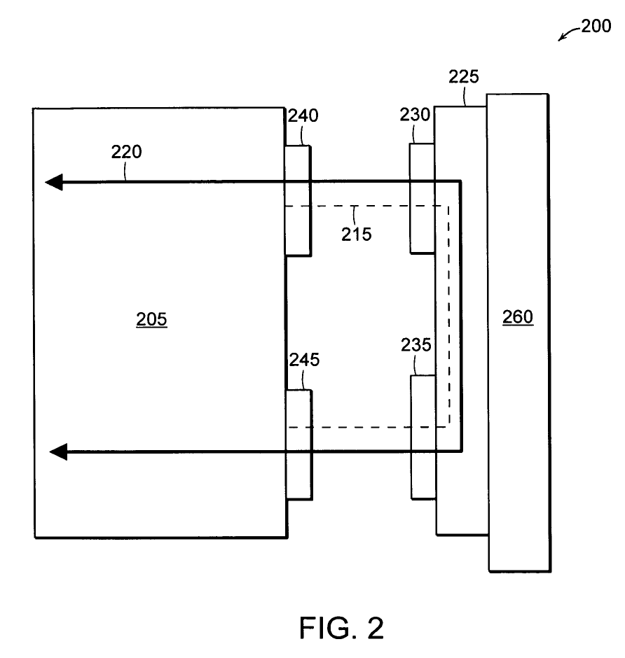

FIG. 2 illustrates a subsystem 200 of another communications system in which an embodiment of the present invention may be employed. The subsystem 200 may have a single card 205, connecting to a backplane 225, that is supported by a chassis 260. As in the subsystem of FIG. 1, the card 205 connects to the backplane 225 through the mating of a card edge connector 240 and a backplane socket 230. In the example of FIG. 2, the subsystem 200 includes only one card 205 and thus may not support inter-module communications between cards connected to the backplane. The subsystem 200 provides communications, as shown by signals 215, between the card 205 and another card (not shown) connected to another backplane (not shown) within a separate subsystem. The subsystem 200 also provides communications traffic 220 through the system.

When utilized with different types of cards, the subsystem 100 of FIG. 1 may be limited. While the sockets 130, 135 may accommodate different types of cards or modules, the chassis 160 may be adapted to accommodate only one type of card into the system 100. For example, the first card 105 may be a larger module that is adapted to connect to either socket 130, 135 by insertion through corresponding slots in the chassis 160. However, the second card 110 may also be adapted to connect to either socket 130, 135, but is a smaller module that cannot be secured directly into the chassis 160. As a result, the prior art system 100 may not be operable with cards of different physical sizes.

Embodiments of the present invention may comprise a system of chassis that can be configured to accept different types of cards or other modules. Specifically, in one embodiment, a first chassis accommodates a communications system having subsystems, and a second chassis is adapted both for insertion into the first chassis and to hold one or more circuit boards in a manner allowing them to operate in the first chassis. Each subsystem, by way of configuring the chassis, may be adapted to operate with multiple types of cards or other modules. For example, a subsystem can first be configured to accept a particular module and can later be reconfigured to accept multiple cards of a different type.

An example of an application in which two types of circuit boards may be used in a first chassis is when an upgraded version of a circuit board and the earlier or legacy version can be used interchangeably. It may be the case that the upgraded circuit board has a different form factor (e.g., smaller); hence, the second chassis (i.e., adapter chassis) may be used to support the upgraded version of the circuit board.

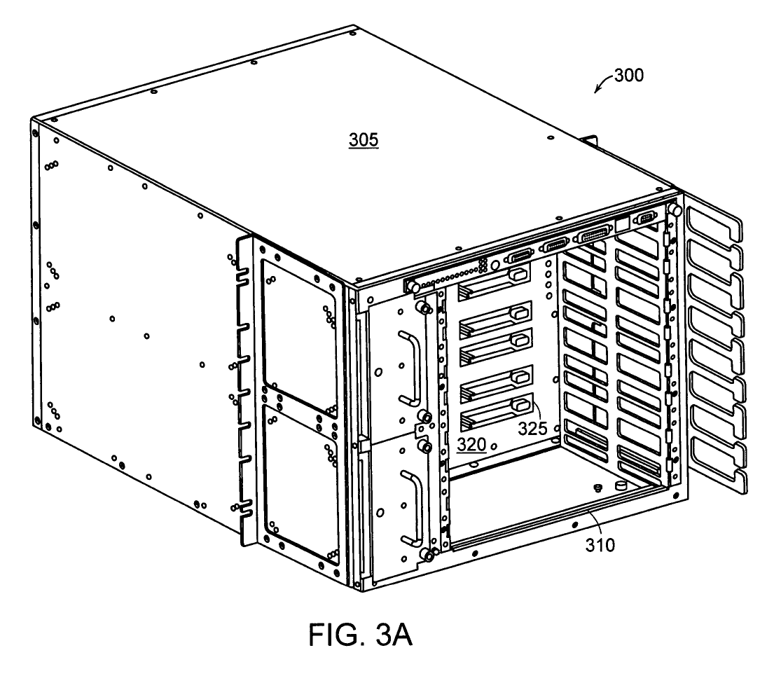

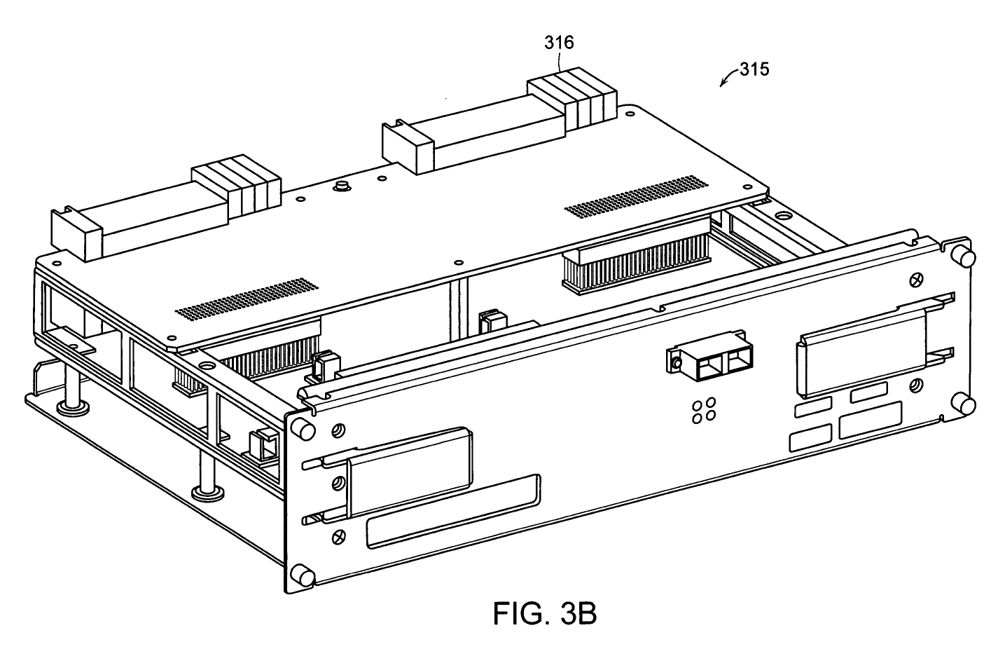

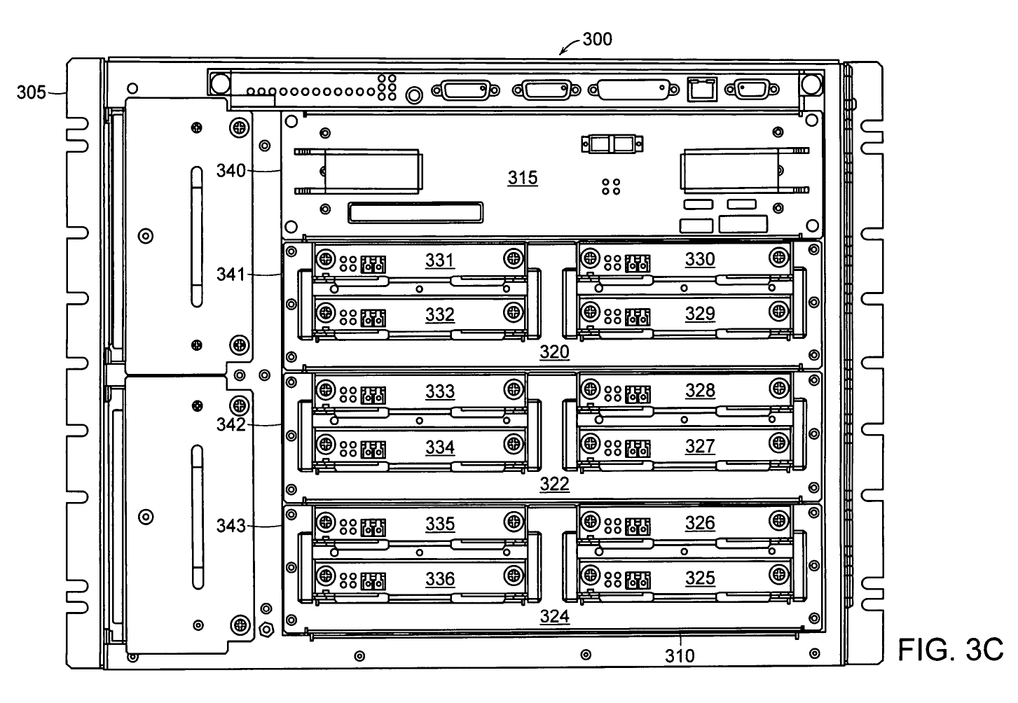

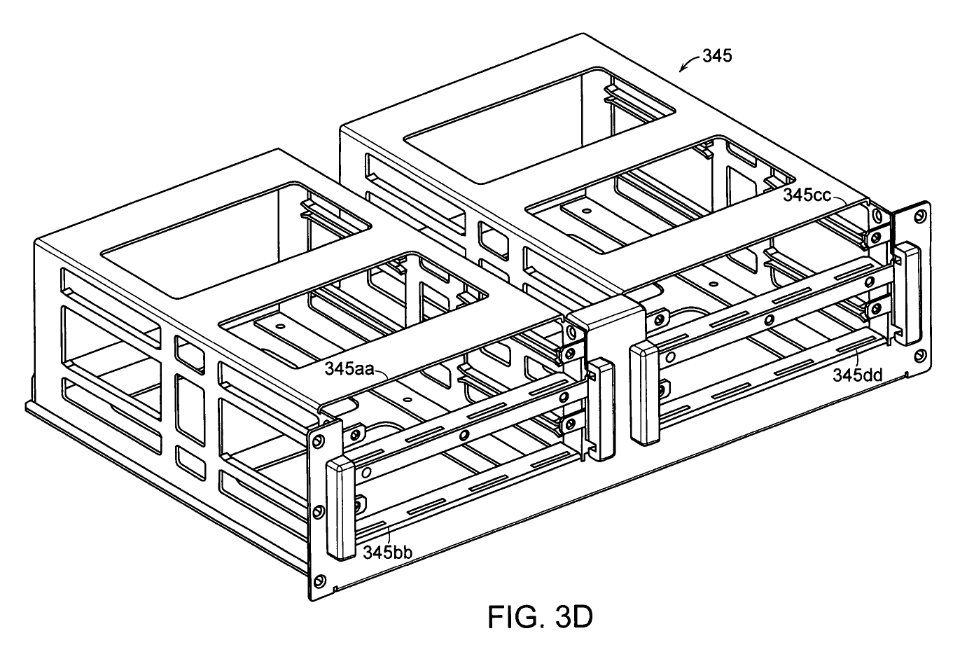

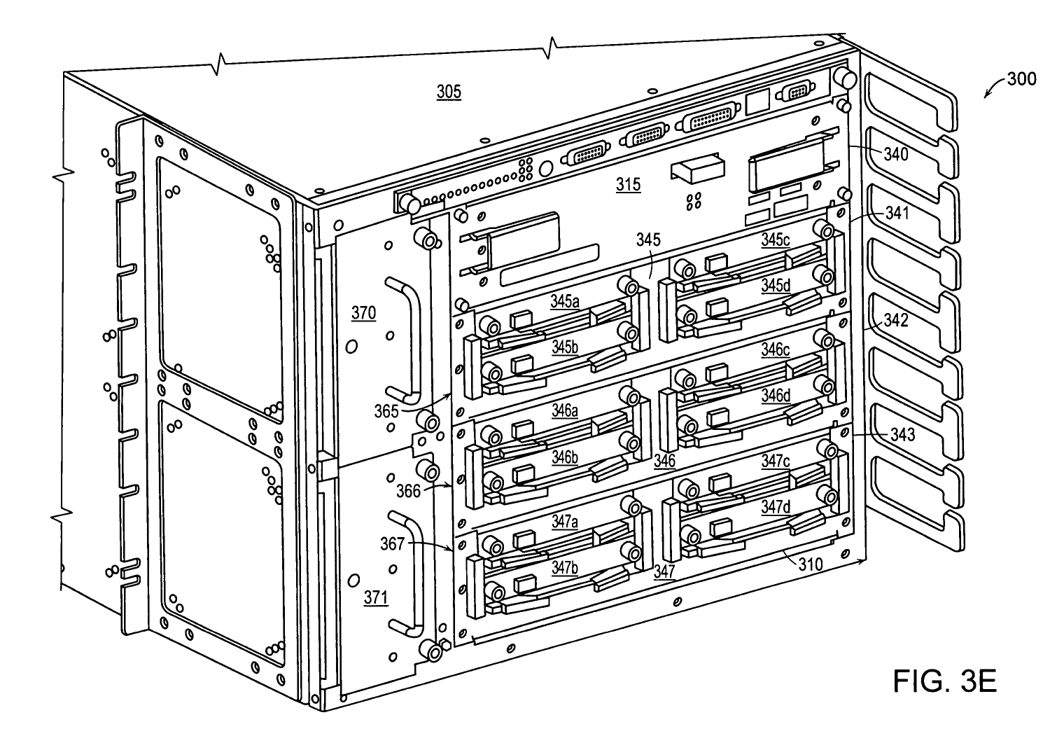

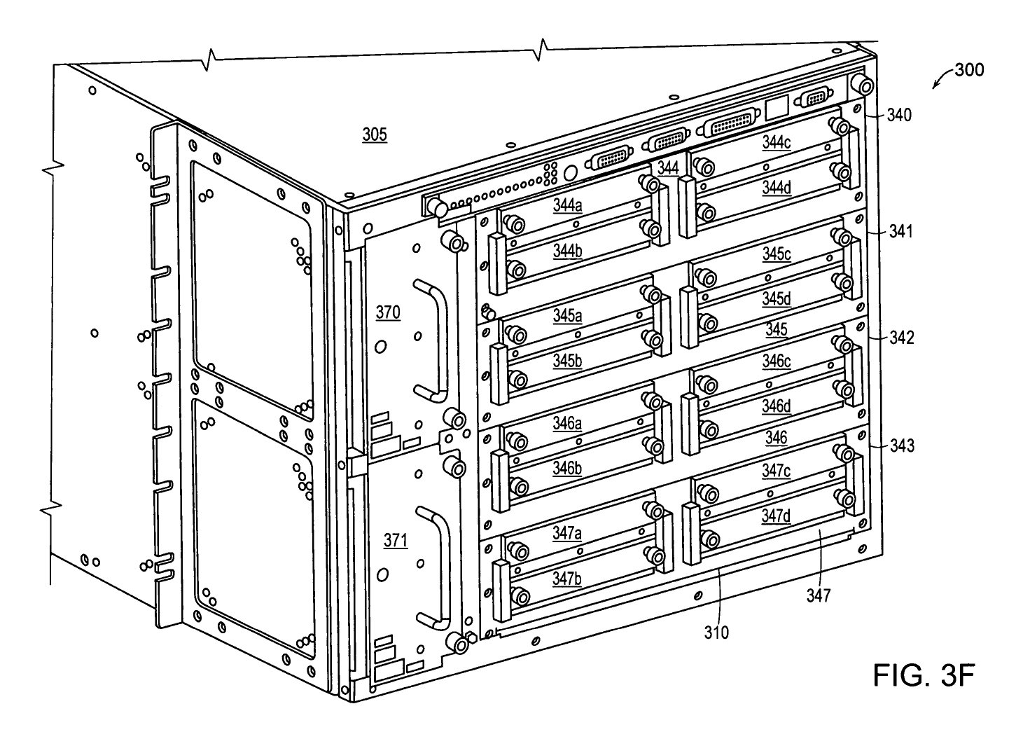

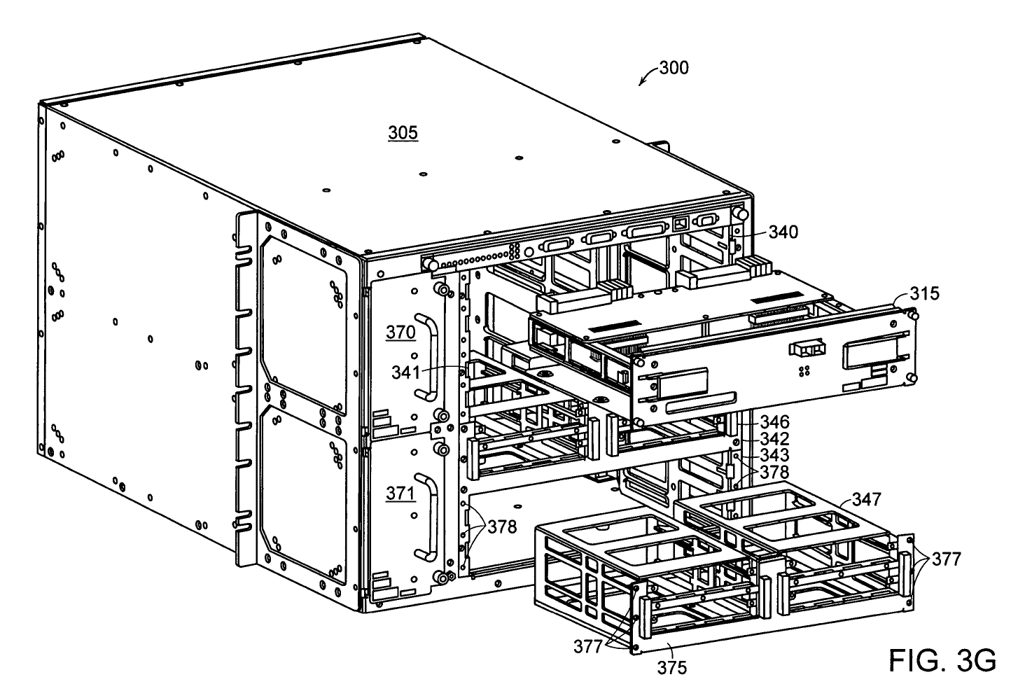

FIG. 3A illustrates a chassis 305 of an exemplary embodiment of the present invention. A system 300 includes a chassis 305 that defines an opening 310 for subsystems (not shown). As shown, this system 300 can hold four subsystems. The subsystems can be multiple-card subsystems, module subsystems, or a combination of both. Towards the back of the chassis 310 is a backplane 320 having sockets 325. Upon insertion of a multiple-card or module subsystem into the chassis 305, a card edge connector mates with a socket, thereby allowing the subsystem to operate with the backplane 320.

FIG. 3B illustrates a module subsystem 315 having card edge connectors 316. Upon insertion of the module subsystem 315 into a chassis, such as the chassis 305 of FIG. 3A, the card edge connectors 316 mate with the sockets 325 on the backplane 320 in the chassis 310.

FIG. 3C is a view of the front of the system 300, with the module subsystem 315 inserted into the chassis 305 through a slot 340 in the front opening of the chassis. The remainder of the opening 310 at slots 341-343 is filled with adapter chassis 320, 322, and 324. The topmost adapter chassis 320 supports four circuit boards 329-332. The middle adapter chassis supports four circuit boards 327, 328, 333, and 334. The bottom adapter chassis supports four circuit boards 325, 326, 335, and 336. The module subsystem 315 may be an upgrade of the circuit boards in the adapter chassis, or vice-versa. For example, in an optical network, the module subsystem 315 may support OC-192 (10 Gbps) communications, and the circuit boards 325-336 may support OC-48 or other lower rate communications.

FIG. 3D illustrates a second (“adapter”) chassis 345 that is adapted to fit into the first or main chassis 305 in place of a module subsystem 315. While the adapter chassis 345 is structured to occupy a slot in the main chassis 305, it is adapted to hold multiple communications modules rather than a module subsystem 315. Each slot 345aa-345dd within the adapter chassis 345 may accommodate a communications module (not shown), such as a circuit board or card, that is compatible to connect with a socket 325 and to operate with the backplane 320. Such cards may be secured in a slot of the adapter chassis 345 via rails located a the sides of the card, fasteners coupled to a card and the card tray 345, or other comparable means. A total of four such cards can be inserted into the adapter chassis 345, with each occupying a separate slot. When more than one such communications module is inserted into the adapter chassis 345, the modules may operate together as a multiple-card subsystem. Thus, the adapter chassis 345 may serve as the support structure for a single subsystem, made up of several communications modules, that may operate within the system 300 of FIG. 3A.

The adapter chassis 345 may be structured so as to serve a number of functions, including securing multiple communications modules within slots 345aa-345dd, occupying a slot within the chassis 305, positioning the modules so as to operate within a chassis 305 of the system 300, and allowing air to flow across the communications modules so that they are adequately cooled during operation in the main chassis 305. Regarding the airflow function, the sides of the adapter chassis 345 have a number of openings positioned so as to expose inserted cards to airflow and to allow air to flow through the adapter chassis 345 with minimal obstruction. Depending on the configuration of the system 300, including placement of fans, the adapter chassis 345 can be modified further to improve airflow. For example, openings in the top, bottom, left or right sides of the chassis may be enlarged, shaped differently, or removed. Alternatively, the sides may be removed altogether, provided that the adapter chassis 345 still has structure to secure and support communications modules within the card tray.

FIG. 3E illustrates the system 300 with a particular configuration of a module subsystem 315 and multiple-card subsystems 365, 366, and 367. A module subsystem 315 occupies the topmost slot 340 of the opening 310 at the front of the main chassis 305. The multiple-card subsystems 365, 366, and 367 comprise an adapter chassis and four communications modules (also referred to as “cards”). For example, the adapter chassis 347 and cards 347a-347d compose the multiple-card subsystem 367, which is inserted horizontally into slot 343 of the opening 310 at the front of the main chassis 305. Likewise, the adapter chassis 345 with cards 345a-d and the adapter chassis 346 with cards 346a-d compose two additional multiple-card subsystems 365, 366, respectively, which are located in slots 341 and 342, respectively, of the opening 310 at the front of the main chassis 305. The cards of each adapter chassis 345-347 each have card edge connector(s), which are adapted to mate with socket(s) on the backplane 320 (as shown in FIG. 3C). Each adapter chassis 345-347 can support its respective cards to operate in the system 300 by aligning the cards to properly connect to the backplane 320 at the rear of the chassis 305. The module subsystem 315 also connects to the backplane 320, and thus all subsystems shown in FIG. 3E operate in the system 300.

This system 300 may also includes two fan trays 370, 371 positioned inside additional openings in the chassis 305 to the left of the opening 310. The fan trays 370, 371 are adapted to position one or more fans (not shown) to propel air through the opening 310, where module and multiple-card subsystems are located. The fan trays 370, 371 may be located such that fans may propel air through all slots of the chassis 305, resulting in cooling for all subsystems operating in the chassis 305. To achieve ideal airflow, space may be allocated within the chassis 305 and adapter chassis 345, 346, 347 so that air from the fans at the fan trays 370, 371 flows through the subsystems with minimal obstruction. For example, the chassis 305 or an additional structure (not shown) may form an opening between the fan trays 370, 371 and opening 310, and the adapter chassis 345-347 may form openings such that air flows through the adapter chassis 345-347 across the cards within them. Such a system of fan trays 370, 371 and fans may enhance the performance of the system 300 by cooling the subsystems positioned inside the chassis 305.

FIG. 3F illustrates the system 300 configured for four multiple-card subsystems, where a combination of adapter chassis 344-347 and respective communications modules (cards) occupy every slot 340-343 of the opening 310 at the front of the chassis 305. This configuration is similar to the configuration of FIG. 3E, except that in FIG. 3F, an additional multiple-card subsystem (adapter chassis 344 and cards 344a-d) is positioned in place of the module subsystem 315, in slot 340.

FIG. 3G illustrates the system 300 in a state of assembly of an alternative configuration of module and multiple-card subsystems. The configuration may include one module subsystem 315 and two multiple-card subsystems, where the module subsystem 315 occupies the topmost slot 340 of opening 310, the multiple-card subsystem (supported by the adapter chassis 346, 347) may occupy two lower slots 342, 343, and the remaining slot 341 may be occupied with either a subsystem 31-5, adapter chassis 247, or, in some embodiments, may remain unoccupied with a blank front panel covering the unoccupied slot for aesthetic purposes. Depending on the system 300 configuration, circuit boards (not shown) may be inserted into the adapter chassis 346, 347 when the adapter chassis 346-347 are either inserted into the chassis 305 (as is illustrated by one of the adapter chassis 346) or outside of the chassis (as is illustrated by the other adapter chassis 347) to form multiple-card subsystems that operate in the system 300.

Both the module subsystem 315 and the lower adapter chassis 347 are outside of the main chassis 305, but are aligned to be inserted into their respective slots 340, 343. The adapter chassis 347 may be inserted into its slot 343 by sliding it through rails within the chassis 305, which may be adapted for accepting module subsystems, adapter chassis or circuit boards. Once inserted, the card tray 347 may be secured into the slot 343 by a fastener or other securing mechanism that prevents the adapter chassis 347 from exiting the slot 343. For example, in this embodiment, the adapter chassis 347 has three circular holes 377 on each the right and left sides of a faceplate 375, which correspond to holes 378 adjacent to the slot 343 at the front panel of the chassis 305. A bolt, screw, clip or other fastener may be inserted into each of these corresponding pairs of holes 377, 378, thereby interconnecting the holes and securing the adapter chassis 347 into the slot 343 of the chassis 305. As a result, the adapter chassis 346, 347 and the module subsystem 315 may be easily removed and/or moved into different slots within the chassis 305, and additional subsystems may be inserted in the same manner, allowing reconfiguration of the system 300 to accommodate a user's requirements.

Embodiments of the present invention may be suitable for use in an optical communications network where it is desirable for communications modules of different structures or sizes to operate within the same system. In the system 300 of FIG. 3E, for example, the module subsystem 315 and the several cards (such as circuit board 345a) may all serve the same function of routing optical communications traffic and, therefore, be adapted to connect with any of the sockets in the backplane at the rear of the chassis 305.

The module subsystem 315 and cards (e.g., circuit board 345a) may be distinct in their level of performance, with the module subsystem 315 having a transfer rate of 10 Gigabits per second or higher, and each card having a transfer rate below 10 Gigabits per second. In this embodiment, the module subsystem 315 connects to four sockets while occupying one slot 340 in the chassis 305, and each card connects to one socket. However, the main chassis 305 is not adopted to hold the cards secure while they operate with the backplane. The system 300 provides a solution by positioning these cards in the adapter chassis 345, 346, 347 that are adapted to occupy slots inside the main chassis 305 and hold their respective cards while they operate with the backplane. As a result, cards that are not adapted for insertion in the main chassis 305 may be secured within the main chassis 305, and a number of cards may be arranged in a subsystem that is modular and easily inserted into or removed from the system 300.

The system 300 of FIGS. 3A-3G can be modified in a number of ways, in order to accommodate modules of different sizes and shapes, a backplane or other circuit of a different configuration, or other structural or connective requirements. An adapter chassis can hold at least one card. An adapter chassis need not have four sides; for example, a card tray could have one side with structure to support communications modules within the chassis. An adapter chassis may be aligned horizontally, vertically, or at other angles when inserted into the main chassis 305. Likewise, cards may be aligned vertically or horizontally within an adapter chassis (e.g., adapter chassis 347). If required by the design of cards or a multiple-card subsystem, the adapter chassis may be structured to occupy more than one slot in the chassis. Such a structure may be useful to accommodate larger communications modules or a larger number of communications modules within a multiple-card subsystem. Modified adapter chassis may also be used in conjunction with other adapter chassis within the same main chassis.

The main chassis 305 can be modified to accommodate different requirements of module subsystems and multiple-card subsystems. For example, the main chassis 305 may be modified to accept any number of module or multiple-card subsystems, determined by a number of sockets on the backplane and corresponding slots in the main chassis 305. These slots need not be stacked, but may be arranged side-by-side or in positions that are not adjacent to one another.

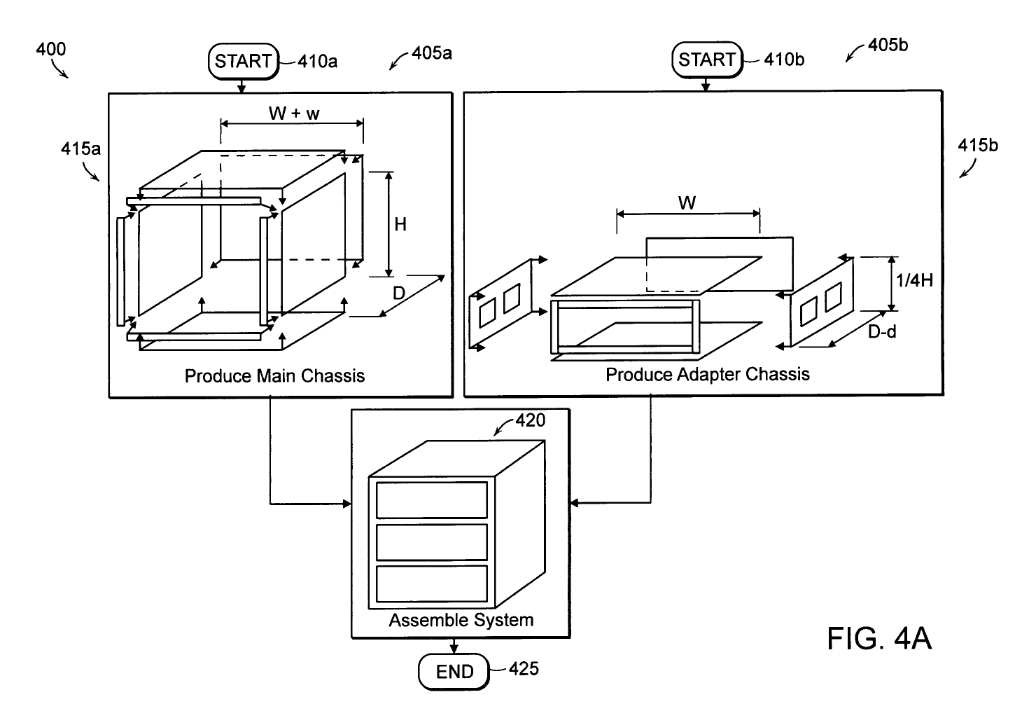

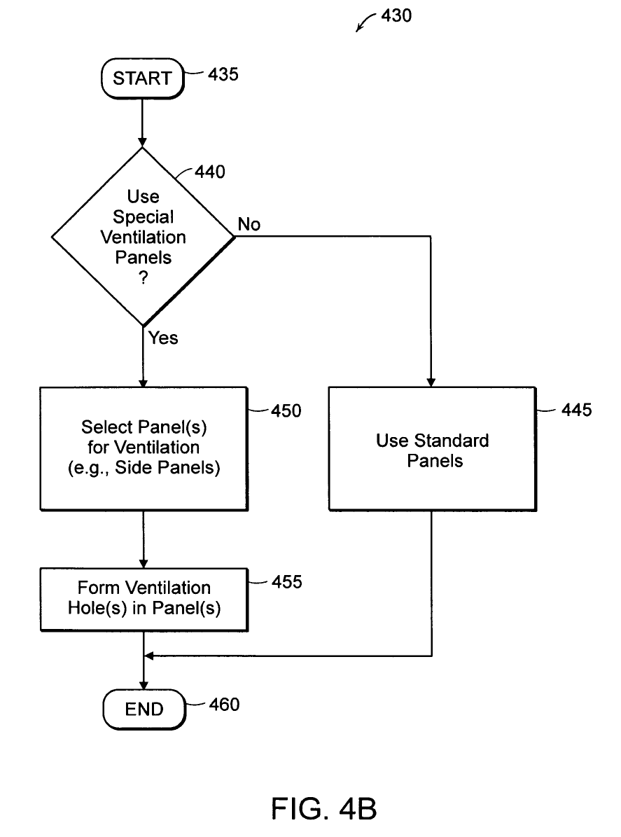

FIG. 4A illustrates an example method 400 of manufacturing a system that includes a main chassis, such as the main chassis 305 of FIG. 3G, and an adapter chassis, such as the adapter chassis 347 of FIG. 3G, according to an embodiment of the present invention. Referring to FIG. 4A, the method 400 may include first and second submethods 405a and 405b for producing the main chassis and adapter chassis. The submethods 405a, 405b may start (steps 410a and 410b) at the same time or at different times. Further, the submethods 405a, 405b may be performed by a single manufacturer or multiple manufacturers, and may be assembled at a single location or multiple locations, including by a user of the system.

The first submethod 405a includes producing the main chassis. The main chassis is produced (step 415a) according to a specification that indicates width, height, depth, and so forth for manufacturing components of the main chassis. The second submethod 405b is produced according to a specification that indicates width, height, depth, and so forth for manufacturing components of the adapter chassis. Based on the foregoing description in reference to FIGS. 1 through 3G, it should be understood that the specification for the adapter chassis is relative to the main chassis. For example, since the adapter chassis in some embodiments fits fully inside the main chassis, the width and height of the adapter chassis is less than the main chassis in those embodiments. Typically, the depth of the adapter chassis is less than the depth of the main chassis to fit in the main chassis in front of a backplane, thereby allowing circuit boards inserting into the adapter chassis to connect directly to the backplane.

The method 400 of manufacturing the system may also include assembling the system (step 420) by configuring the main chassis with one or more adapter chassis. A manufacturer, assembly contractor, network service provider, or other party may perform the system assembly (step 420) depending on the tools or skills required for a given embodiment. In typical cases, after the system assembly (step 420), the method 400 may end (step 425), and the system may be populated with circuit boards, delivered to a customer, or deployed in a network.

FIG. 4B is an example submethod 430 of manufacturing an adapter chassis, such as the adapter chassis 347 of FIG. 3G. The submethod 430 starts (step 435) by determining whether special ventilation panels (step 440) will be used. In the case of the adapter chassis 347 of FIG. 3G, the ventilation panels are side panels. In other configurations, the ventilation panels may be the top and bottom panels, front and rear panels, or combinations of any panels on the six sides of the adapter chassis. If special ventilation panels are not to be used, the manufacturer (or assembler) may produce or use standard panels (step 445). If special ventilation panels are to be used, the submethod 430 proceeds to have the manufacturer select which panel(s) is/are to have the special ventilation holes (step 450), followed by the manufacturer's forming the ventilation hole(s) in the panel(s) (step 455). The submethod ends (step 460) with the panels being integrated with other components of the adapter chassis.

It should be understood that any form of manufacturing may be employed to produce the main chassis or adapter chassis. For example, cutting, bending, or molding techniques may be employed. Further, any type of metal, non-metal, alloy, or other structural components may be used to form either or both of the main chassis or adapter chassis. Manufacturing the chassis may include using the same or different techniques, and may use a single material or multiple materials in any combination. Further, assembling the main or adapter chassis may use screws, rivets, welding, or other techniques to connect components together to form the main or adapter chassis in a manner for supporting circuit boards which is accepted in an industry in which the main or adapter chassis is to be deployed.

While this invention has been particularly shown and described with references to preferred embodiments thereof, it will be understood by those skilled in the art that various changes in form and details may be made therein without departing from the scope of the invention encompassed by the appended claims.

What is claimed is:

1. A system for positioning circuit boards, comprising:
a first chassis adapted to receive first circuit boards to operate in the first chassis; and
a second chassis adapted to fit inside the first chassis absent at least a subset of the first circuit boards and to receive second circuit boards in a manner enabling the second circuit boards to operate in the first chassis.

2. The system of claim 1 further comprising a third chassis adapted to fit inside the first chassis while the second chassis is inside the first chassis.

3. The system of claim 1 wherein the second circuit boards are positioned horizontally in the first chassis.

4. The system of claim 1 wherein the second chassis includes a structure forming at least one opening positioned to allow air to flow through the second chassis.

5. The system of claim 4 further comprising at least one fan tray positioned inside the first chassis that propels air through the at least one opening of the second chassis.

6. The system of claim 5 wherein the first chassis includes multiple slots available to receive the second chassis and wherein the at least one fan tray propels air through the at least one opening of the second chassis while the second chassis is positioned inside any of the multiple slots of the first chassis.

7. The system of claim 1 further comprising an arrangement of at least one of the first circuit boards and at least one of the second chassis positioned inside the first chassis with at least one of the second circuit boards, wherein the at least one first and second circuit boards operate with a third circuit board also in the first chassis.

8. The system of claim 1 wherein the second chassis is secured inside the first chassis by at least one securing mechanism located at a front panel of the first chassis configured to receive interconnection with the securing mechanism.

9. The system of claim 1 wherein the first and second circuit boards are adapted for use in an optical communications network.

10. The system of claim 1 wherein the second chassis is not configured to receive the first circuit boards.

11. The system of claim 1 wherein the first circuit boards include a communications module having a transfer rate about or over 10 Gigabits per second, and the second circuit boards include a communications module having a transfer rate less than 10 Gigabits per second.

12. A method of manufacturing configurable circuit board chassis, comprising:
producing a first chassis adapted to receive first circuit boards; and
producing a second chassis adapted to fit inside the first chassis in place of at least one first circuit board and to receive second circuit boards in a manner enabling the second circuit boards to operate in the first chassis.

13. The method of claim 12 further comprising producing at least one additional second chassis that may be fit inside the first chassis while the second chassis is inside the first chassis.

14. The method of claim 12 further comprising forming at least one hole in the second chassis to allow air to flow through the second chassis.

15. The method of claim 14 further comprising positioning at least one fan tray inside the first chassis to propel air through the at least one hole of the second chassis.

16. The method of claim 12 further comprising positioning a third circuit board in the first chassis, wherein the third circuit board communicates with the first or second circuit boards operating inside the first chassis.

17. The method of claim 12 further comprising securing the second chassis into the first chassis with at least one fastener positioned at a face of the first chassis that receives the second chassis.

18. The method of claim 12 wherein producing a second chassis includes forming the second chassis in a manner that the first circuit board cannot fit inside the second chassis.

19. A system for positioning circuit boards, comprising:
means for positioning first circuit boards inside a first chassis; and
means for positioning a second chassis inside the first chassis in place of at least one first circuit board, the second chassis being adapted to receive second circuit boards in a manner enabling the second circuit boards to operate in the first chassis.
